(19) United States
(12) Patent Application Publication
(10) Pub. No.: US 2020/0073189 A1
(43) Pub. Date: Mar. 5, 2020

(54) ACTIVE MATRIX SUBSTRATE, DISPLAY DEVICE, AND METHOD FOR MANUFACTURING ACTIVE MATRIX SUBSTRATE

(71) Applicant: Sharp Kabushiki Kaisha, Sakai City (JP)

(72) Inventors: Hitoshi TAKAHATA, Sakai City (JP); Tohru DAITOH, Sakai City (JP); Hajime IMAI, Sakai City (JP); Tetsuo KIKUCHI, Sakai City (JP); Kengo HARA, Sakai City (JP); Masahiko SUZUKI, Sakai City (JP); Setsuji NISHIMIYA, Sakai City (JP); Teruyuki UEDA, Sakai City (JP); Masamitsu YAMANAKA, Sakai City (JP); Yoshihito HARA, Sakai City (JP)

(21) Appl. No.: 16/548,886

(22) Filed: Aug. 23, 2019

Related U.S. Application Data
(60) Provisional application No. 62/724,661, filed on Aug. 30, 2018.

(51) Int. Cl. G02F 1/1362; H01L 27/12; H01L 27/32

(52) U.S. Cl. CPC G02F 1/136286; G02F 1/136209; G02F 2001/13629; H01L 27/3262; H01L 27/1244

(57) ABSTRACT

[Object]

To provide an active matrix substrate (1) that includes an organic insulating film (OIL) and first source layers (FSL2 to FSL4) and second source layers (SSL1 to SSL3), which constitute two-layer wiring lines, and that is produced with a high yield.

[Solution]

In an active matrix substrate (1), of the first source layers (FSL2 to FSL4) and the second source layers (SSL1 to SSL3), the second source layers (SSL1 to SSL3) arranged further from the substrate (2) are in contact with an organic insulating film (OIL) with a second inorganic insulating film (SINOIL) interposed therebetween.

### TECHNICAL FIELD

The present disclosure relates to an active matrix substrate, a display device, and a method for manufacturing an active matrix substrate.

### BACKGROUND ART

To date, regarding active matrix substrates included in display devices, for example, liquid crystal display devices, configurations in which an organic insulating film is used as an insulating film that covers a source electrode and a drain electrode of a TFT element (thin film transistor element) of an active matrix substrate and a source wiring line electrically connected to the source electrode have been known (PTL 1 and the like).

In recent years, an increase in the resolution (for example, a resolution increase to 8K) and an increase in the size (for example, an increase to 80 inches) of display devices have steadily advanced.

In accordance with an increase in resolution, the number of pixels increases, the pixel being a unit of display. Consequently, the number of source wiring lines and the number of gate wiring lines required for performing display of all pixels increase. Therefore, to realize an increase in resolution of the display device without an increase in size of the display device, it is necessary to thin the source wiring line and the gate wiring line.

In addition, in the case of a large display device, the wiring length of the source wiring line and the wiring length of the gate wiring line are large, and the source-gate capacitance increases correspondingly. As a result, to suppress an increase in the source-gate capacitance, it is necessary to thin the source wiring line and the gate wiring line.

For the above-described reasons, it is necessary to thin the source wiring line and the gate wiring line. However, in accordance with thinning the source wiring line and the gate wiring line, breakage of these wiring lines is more likely to occur during production of a display device, and a problem of a reduction in yield of the display device results.

### CITATION LIST

### Patent Literature

PTL 1: Japanese Unexamined Patent Application Publication No. 10-260646 (published on Sep. 29, 1998)

### SUMMARY OF INVENTION

### Technical Problem

Accordingly, to suppress a reduction in yield of the display device due to breakage of the wiring lines during production of the display device, the following configuration is considered.

FIG. 10 is a drawing illustrating a problem in the case in which a second source wiring line SSL is in contact with an organic insulating film OIL in an active matrix substrate 100 including the organic insulating film OIL, a thinned first source wiring line FSL, and a thinned second source wiring line SSL.

As shown in FIG. 10, the active matrix substrate 100 includes a substrate 101, a gate insulating film GIL that is an inorganic insulating film disposed on the substrate 101, the first source wiring line FSL disposed on the gate insulating film GIL so as to have a predetermined pattern, a first inorganic insulating film INOIL disposed so as to have an opening on the first source wiring line FSL, the second source wiring line SSL electrically connected to the first source wiring line FSL via the opening, and the organic insulating film OIL disposed so as to cover the second source wiring line SSL and the first inorganic insulating film INOIL.

The first source wiring line FSL and the second source wiring line SSL are thinned source wiring lines and are in contact with each other in the opening portion formed in the first inorganic insulating film INOIL. As described above, in the active matrix substrate 100, the thinned source wiring line is a two-layer wiring line composed of the first source wiring line FSL and the second source wiring line SSL.

According to the active matrix substrate 100 having such a configuration, even when breakage of any one of the first source wiring line FSL and the second source wiring line SSL occurs, no reduction in yield of the display device results. Therefore, it is anticipated that a reduction in yield of the display device will be suppressed.

However, in the case of the active matrix substrate 100, there is a problem in that the second source wiring line SSL loses the role of the wiring line for the reason described below. Therefore, the second source wiring line SSL does not substantially play the role of a two-layer wiring line, and a reduction in yield of the display device cannot be suppressed.

To realize a reduction in resistance of the wiring line, the thinned first source wiring line FSL included in the active matrix substrate 100 is composed of a single-layer film of, for example, copper (Cu), silver (Ag), molybdenum (Mo), aluminum (Al), tungsten (W), tantalum (Ta), chromium (Cr), or titanium (Ti), a multilayer film containing at least one of these metals, or an alloy film of at least two of these metals. Meanwhile, as shown in FIG. 10, the active matrix substrate 100 has a configuration in which the second source wiring line SSL that is a layer on the first source wiring line FSL is in direct contact with the organic insulating film OIL, that is, a configuration in which the organic insulating film OIL directly covers the second source wiring line SSL.

In many cases of such a configuration, to realize a reduction in resistance of the wiring line, the thinned second source wiring line SSL is composed of a single-layer film of a metal that reacts with the organic insulating film OIL (for example, copper (Cu), silver (Ag), or molybdenum (Mo)), a multilayer film which contains at least one of these metals and in which any one of copper (Cu), silver (Ag), and molybdenum (Mo) is present on the organic insulating film OIL side, or an alloy film of at least two of these metals.

In such a case, at the interface between the second source wiring line SSL and the organic insulating film OIL, oxygen or hydrogen contained in the organic insulating film OIL reacts with a metal material constituting the second source wiring line SSL, and the metal material constituting the second source wiring line SSL forms a metal oxide. The metal oxide formed on the second source wiring line SSL, as described above, is an insulator, and, therefore, the second source wiring line SSL loses the role of a wiring line.

The present disclosure was realized in consideration of the above-described problems, and an object is to provide an active matrix substrate that includes an organic insulating film and a source wiring line composed of a two-layer wiring line and that is produced with a high yield, to provide a method for manufacturing the active matrix substrate, and to provide a display device including the active matrix substrate.

### Solution to Problem

(1) An embodiment according to the present invention is an active matrix substrate including a substrate provided with a first conductive layer, a second conductive layer, and an organic insulating film, wherein the first conductive layer and the second conductive layer are partly stacked, the organic insulating film is arranged further than the first conductive layer and the second conductive layer from the substrate, and, of the first conductive layer and the second conductive layer, the conductive layer arranged further from the substrate is in contact with the organic insulating film with an inorganic insulating film interposed therebetween.

(2) An embodiment according to the present invention is the active matrix substrate having the configuration described in (1) above, wherein a bottom-gate transistor element including a source electrode, a drain electrode, a semiconductor layer, and a gate electrode arranged nearer than the semiconductor layer to the substrate is included, the first conductive layer is arranged nearer than the second conductive layer to the substrate, and the first conductive layer is composed of the same layer as the source electrode and the drain electrode.

(3) An embodiment according to the present invention is the active matrix substrate having the configuration described in (1) above, wherein a top-gate transistor element including a source electrode, a drain electrode, a semiconductor layer, and a gate electrode arranged further than the semiconductor layer from the substrate is included, the first conductive layer is arranged nearer than the second conductive layer to the substrate, and the first conductive layer is composed of the same layer as the source electrode and the drain electrode.

(4) An embodiment according to the present invention is the active matrix substrate having the configuration described in (1) above, wherein a top-gate transistor element including a source electrode, a drain electrode, a semiconductor layer, a gate electrode arranged further than the semiconductor layer from the substrate, and a light-shielding layer arranged nearer than the source electrode, the drain electrode, and the semiconductor layer to the substrate is included, the first conductive layer is arranged further than the second conductive layer from the substrate, the first conductive layer is composed of the same layer as the source electrode and the drain electrode, and the second conductive layer is composed of the same layer as the light-shielding layer.

(5) An embodiment according to the present invention is the active matrix substrate having the configuration described in any one of (1) to (3) above, wherein the second conductive layer in contact with the organic insulating film with the inorganic insulating film interposed therebetween is composed of one film selected from a single-layer film made of any one of copper, silver, and molybdenum, a multilayer film which contains at least one of copper, silver, and molybdenum and in which any one of copper, silver, and molybdenum is present on the organic insulating film side, and an alloy film of at least two of copper, silver, and molybdenum.

(6) An embodiment according to the present invention is the active matrix substrate having the configuration described in (1) or (4) above, wherein the first conductive layer in contact with the organic insulating film with the inorganic insulating film interposed therebetween is composed of one film selected from a single-layer film made of any one of copper, silver, and molybdenum, a multilayer film which contains at least one of copper, silver, and molybdenum and in which any one of copper, silver, and molybdenum is present on the organic insulating film side, and an alloy film of at least two of copper, silver, and molybdenum.

(7) An embodiment according to the present invention is the active matrix substrate having the configuration described in any one of (2) to (4) above, wherein the semiconductor layer is an oxide semiconductor layer.

(8) An embodiment according to the present invention is a display device including the active matrix substrate according to any one of (1) to (7) above.

(9) An embodiment according to the present invention is the display device having the configuration described in (8) above, wherein the active matrix substrate and a counter substrate arranged opposing the active matrix substrate are included.

(10) An embodiment according to the present invention is a method for manufacturing an active matrix substrate including the steps of, on a substrate, forming a first conductive layer, forming a second conductive layer, and forming an organic insulating film, wherein in the forming of a first conductive layer and the forming of a second conductive layer, the first conductive layer and the second conductive layer are partly stacked, and forming an inorganic insulating film so as to cover the conductive layer, of the first conductive layer and the second conductive layer, arranged further from the substrate is performed after the forming of a first conductive layer and the forming of a second conductive layer and before the forming of an organic insulating film.

(11) An embodiment according to the present invention is the method for manufacturing an active matrix substrate described in (10) above, wherein the forming of a first conductive layer is performed before the forming of a second conductive layer, and in the forming of a first conductive layer, the first conductive layer is composed of the same layer as a source electrode and a drain electrode of a bottom-gate transistor element including the source electrode, the drain electrode, a semiconductor layer, and a gate electrode arranged nearer than the semiconductor layer to the substrate.

(12) An embodiment according to the present invention is the method for manufacturing an active matrix substrate described in (10) above, wherein the forming of a first conductive layer is performed before the forming of a second conductive layer, and in the forming of a first conductive layer, the first conductive layer is composed of the same layer as a source electrode and a drain electrode of a top-gate transistor element including the source electrode, the drain electrode, a semiconductor layer, and a gate electrode arranged further than the semiconductor layer from the substrate.

(13) An embodiment according to the present invention is the method for manufacturing an active matrix substrate described in (10) above, wherein the forming of a second conductive layer is performed before the forming of a first conductive layer, and in the forming of a first conductive layer, the first conductive layer is composed of the same layer as a source electrode and a drain electrode of a top-gate transistor element including the source electrode, the drain electrode, a semiconductor layer, a gate electrode arranged further than the semiconductor layer from the substrate, and a light-shielding layer arranged nearer than the source electrode, the drain electrode, and the semiconductor layer to the substrate is included, and in the forming of a second conductive layer, the second conductive layer is composed of the same layer as the light-shielding layer.

### Advantageous Effects of Invention

An active matrix substrate that includes an organic insulating film and a source wiring line composed of a two-layer wiring line and that is produced with a high yield can be realized, and a method for manufacturing the active matrix substrate and a display device including the active matrix substrate can be realized.

### BRIEF DESCRIPTION OF DRAWINGS

FIG. 1(a) is a diagram showing a region in which a TFT element and a pixel electrode are disposed in an active matrix substrate according to a first embodiment, and FIG. 1(b) is a diagram showing an end region including a terminal portion in the active matrix substrate according to the first embodiment.

FIG. 2 is a diagram illustrating the production steps of the active matrix substrate according to the first embodiment shown in FIG. 1.

FIG. 3 is a diagram illustrating the steps from the step of forming a gate layer on a substrate to the step of peeling a fourth resist of the production steps of the active matrix substrate according to the first embodiment shown in FIG. 2.

FIG. 4 is a diagram illustrating the steps from the step of forming a second source layer to the step of peeling a sixth resist of the production steps of the active matrix substrate according to the first embodiment shown in FIG. 2.

FIG. 5 is a diagram showing a schematic configuration of a display device including the active matrix substrate according to the first embodiment.

FIG. 6(a) is a diagram showing a region in which a TFT element and a pixel electrode are disposed in an active matrix substrate according to a second embodiment, and FIG. 6(b) is a diagram showing an end region including a terminal portion in the active matrix substrate according to the second embodiment.

FIG. 7 is a diagram illustrating the production steps of the active matrix substrate according to the second embodiment shown in FIG. 6.

FIG. 8(a) is a diagram showing a region in which a TFT element and a pixel electrode are disposed in an active matrix substrate according to a third embodiment, and FIG. 8(b) is a diagram showing an end region including a terminal portion in the active matrix substrate according to the third embodiment.

FIG. 9 is a diagram illustrating the production steps of the active matrix substrate according to the third embodiment shown in FIG. 8.

FIG. 10 is a diagram showing an active matrix substrate including an organic insulating film, a thinned first source wiring line, and a thinned second source wiring line and is a diagram illustrating a problem in the case in which the second source wiring line is in contact with the organic insulating film.

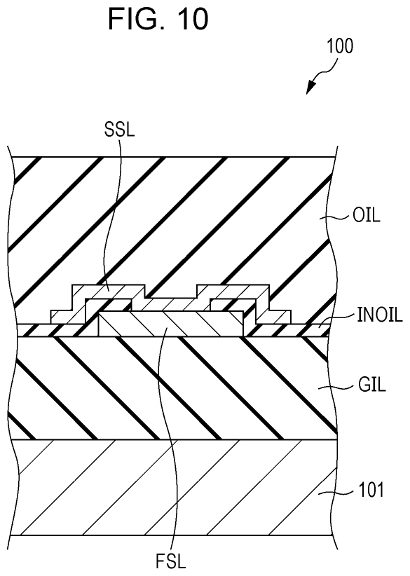

### DESCRIPTION OF EMBODIMENTS

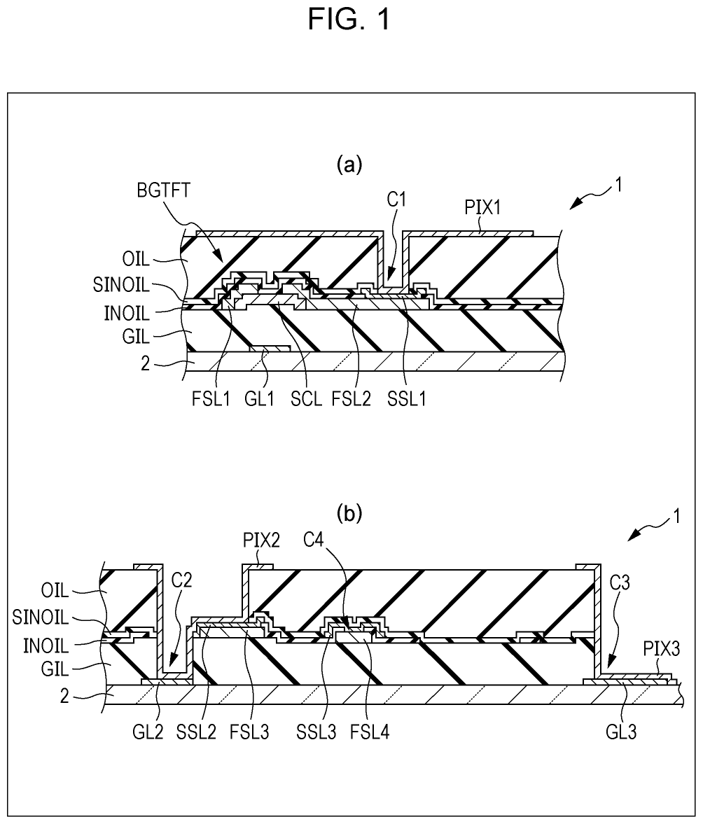

The embodiments according to the present disclosure will be described below with reference to FIG. 1 to FIG. 9. Hereafter, for the sake of facilitating explanations, a configuration having the same function as the configuration described in the specific embodiment is indicated by the same references, and explanations thereof may be omitted.

### First Embodiment

An active matrix substrate 1 according to a first embodiment and a display device 6 including the active matrix substrate 1 will be described below with reference to FIG. 1 to FIG. 5.

FIG. 1(a) is a diagram showing a region in which a TFT element BGTFT and a pixel electrode PIX1 are disposed in the active matrix substrate 1, and FIG. 1(b) is a diagram showing an end region including a terminal portion in the active matrix substrate 1.

Gate layers GL1, GL2, and GL3 are formed by etching the same layer; the gate layer GL1 is a gate electrode, the gate layer GL2 is part of a gate-source contact portion, and the gate layer GL3 is part of the terminal portion. The gate layers GL1, GL2, and GL3 may be composed of a single-layer film of, for example, copper (Cu), silver (Ag), molybdenum (Mo), aluminum (Al), tungsten (W), tantalum (Ta), chromium (Cr), or titanium (Ti), a multilayer film containing at least one of these metals, or an alloy film of at least two of these metals.

First source layers FSL1 to FSL4 (first conductive layers) are formed by etching the same layer; the first source layer FSL1 is a source electrode of the TFT element BGTFT, the first source layer FSL2 is a drain electrode of the TFT element BGTFT, the first source layer FSL3 is part of the gate-source contact portion, and the first source layer FSL4 is part of a gate-source cross portion. The first source layers FSL1 to FSL4 may be composed of a single-layer film of, for example, copper (Cu), silver (Ag), molybdenum (Mo), aluminum (Al), tungsten (W), tantalum (Ta), chromium (Cr), or titanium (Ti), a multilayer film containing at least one of these metals, or an alloy film of at least two of these metals.

Second source layers SSL1 to SSL3 (second conductive layers) are formed by etching the same layer; the second source layer SSL1 is a drain electrode of the TFT element BGTFT, the second source layer SSL2 is part of the gate-source contact portion, and the second source layer SSL3 is part of the gate-source cross portion. To realize a reduction in resistance of the wiring line, the second source wiring lines SSL1 to SSL3 may be composed of a single-layer film of, for example, copper (Cu), silver (Ag), or molybdenum (Mo), a multilayer film which contains at least one of these metals and in which any one of copper (Cu), silver (Ag), and molybdenum (Mo) is present on the organic insulating film OIL side, or an alloy film of at least two of these metals.

As shown in FIG. 1(a), the active matrix substrate 1 includes a bottom-gate TFT element BGTFT. The bottom-gate TFT element BGTFT includes the gate layer GL1 serving as a gate electrode formed on a substrate 2, a gate insulating film GIL serving as an inorganic insulating film formed so as to cover the gate layer GL1, a semiconductor layer SCL formed on the gate insulating film GIL, and the first source layer FSL1 serving as the source electrode and the first source layer FSL2 serving as the drain electrode that are formed on the semiconductor layer SCL.

In the present embodiment, a glass substrate is used as the substrate 2, but the present embodiment is not limited to this. For example, a resin substrate or the like may be used.

In the present embodiment, a silicon nitride film is used as the gate insulating film GIL, but the present embodiment is not limited to this. For example, a silicon oxynitride film or a silicon oxide film may be used.

In the present embodiment, an oxide semiconductor layer is used as the semiconductor layer SCL. In this regard, for example, an oxide semiconductor layer containing In, Ga, or Zn may be used as the oxide semiconductor layer, but the present embodiment is not limited to this. For example, a polycrystalline silicon layer or an amorphous silicon layer may be used as the semiconductor layer.

As shown in FIG. 1(a), in the region in which the TFT element BGTFT and the pixel electrode PIX1 are disposed in the active matrix substrate 1, a first inorganic insulating film INOIL is disposed so as to cover the TFT element BGTFT and to have an opening over the first source layer FSL2 serving as a drain electrode. Then, the first source layer FSL2 is electrically connected to the second source layer SSL1 via the opening. In addition, a second inorganic insulating film SINOIL is disposed so as to cover the first inorganic insulating film INOIL and part of the second source layer SSL1 and to have an opening over the second source layer SSL1.

In the present embodiment, a silicon oxide film is used as the first inorganic insulating film INOIL, but the present embodiment is not limited to this. For example, a silicon nitride film or a silicon oxynitride film may be used.

In the present embodiment, a silicon nitride film is used as the second inorganic insulating film SINOIL, but the present embodiment is not limited to this. For example, a silicon oxide film or a silicon oxynitride film may be used.

In addition, the organic insulating film OIL is disposed so as to cover the second inorganic insulating film SINOIL and to have an opening directly over the opening in the second inorganic insulating film SINOIL. A contact hole C1 is formed by the opening in the organic insulating film OIL and the opening in the second inorganic insulating film SINOIL.

In the present embodiment, a photosensitive positive-type organic insulating film is used as the organic insulating film OIL, and the opening that constitutes part of the contact hole C1 is formed by exposure and development. Regarding the organic insulating film OIL, for example, a negative-type organic insulating film may be used or an organic insulating film not having photosensitivity may be used. In this regard, in the case where an organic insulating film having no photosensitivity is used, an opening may be formed in the organic insulating film having no photosensitivity by separately etching the organic insulating film having no photosensitivity by using a patterned resist film as a mask.

As shown in FIG. 1(a), the pixel electrode PIX1 disposed on the organic insulating film OIL is electrically connected to the second source layer SSL1 serving as the drain electrode via the contact hole C1. In this regard, the conductive members PIX2 and PIX3 shown in FIG. 1(b) and the pixel electrode PIX1 are formed by etching the same layer. The pixel electrode PIX1 and the conductive members PIX2 and PIX3 in the present embodiment are made of ITO (indium tin oxide) but are not limited to this and may be made of, for example, IZO (indium zinc oxide).

As shown in FIG. 1(b), the gate-source contact portion including a contact hole C2, the terminal portion including a contact hole C3, and the gate-source cross portion including a contact hole C4 are disposed in the end region including the terminal portion of the active matrix substrate 1.

In the gate-source contact portion, the first source layer FSL3 and the second source layer SSL2 are stacked so as to constitute a two-layer wiring line. The first source layer FSL3 and the second source layer SSL2 are electrically connected to the gate layer GL2 by the conductive member PIX2 via the contact hole C2.

In the gate-source cross portion, the first source layer FSL4 is electrically connected to the second source layer SSL3 via the contact hole C4.

In the terminal portion, the gate layer GL3 is electrically connected to the conductive member PIX3 via the contact hole C3.

In the active matrix substrate 1, the gate layer GL3 and the conductive member PIX3 that serve as the terminal portion, the conductive member PIX2, the gate layer GL2, and the gate layer GL1 that serves as the gate electrode are electrically connected to each other, and a gate signal input from the terminal portion is transmitted to the gate electrode.

In the active matrix substrate 1, a source signal input from a source signal (image signal) input terminal portion (not shown in the drawing) is transmitted to the pixel electrode PIX1 via the first source layer FSL4, the second source layer SSL3, the first source layer FSL1 serving as the source electrode, and the first source layer FSL2 serving as the drain electrode.

The active matrix substrate 1 has a two-layer wiring structure in each of the drain electrode portion of the TFT element BGTFT, the gate-source contact portion, and the gate-source cross portion. Specifically, in the drain electrode portion of the TFT element BGTFT, the first source layer FSL2 and the second source layer SSL1 are stacked so as to constitute the two-layer wiring line. In the gate-source contact portion, the first source layer FSL3 and the second source layer SSL2 are stacked so as to constitute the two-layer wiring line. In the gate-source cross portion, the first source layer FSL4 and the second source layer SSL3 are stacked so as to constitute the two-layer wiring line.

As described above, the active matrix substrate 1 includes the organic insulating film OIL and the two-layer wiring structures composed of the first source layers FSL2 to FSL4 and the second source layers SSL1 to SSL3. However, since the second inorganic insulating film SINOIL is disposed between the second source layers SSL1 to SSL3 that are upper layers of the two-layer wiring structures and the organic insulating film OIL, the second source layers SSL1 to SSL3 are not in direct contact with the organic insulating film OIL. Therefore, the metal material constituting the second source layers SSL1 to SSL3 can be suppressed from reacting with oxygen or hydrogen contained in the organic insulating film OIL, and the metal material constituting the second source layers SSL1 to SSL3 can be suppressed from forming a metal oxide. Consequently, according to the above-described configuration, the active matrix substrate 1 that includes the organic insulating film OIL and the source wiring line composed of the two-layer wiring line and that is produced with a high yield can be realized.

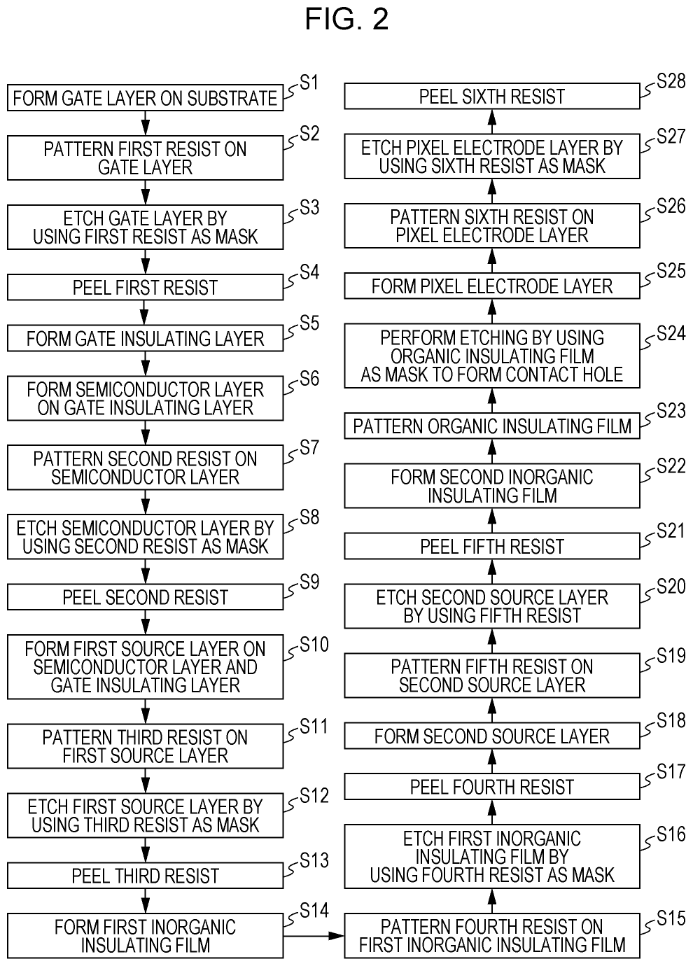

The production steps of the active matrix substrate 1 will be described below with reference to FIG. 2 to FIG. 4.

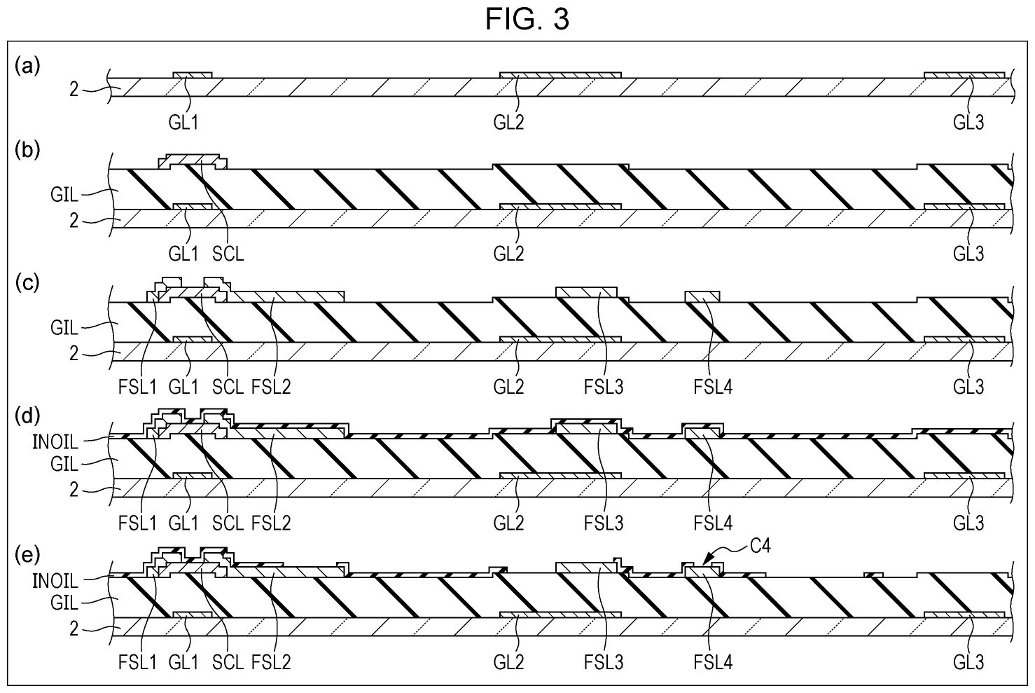

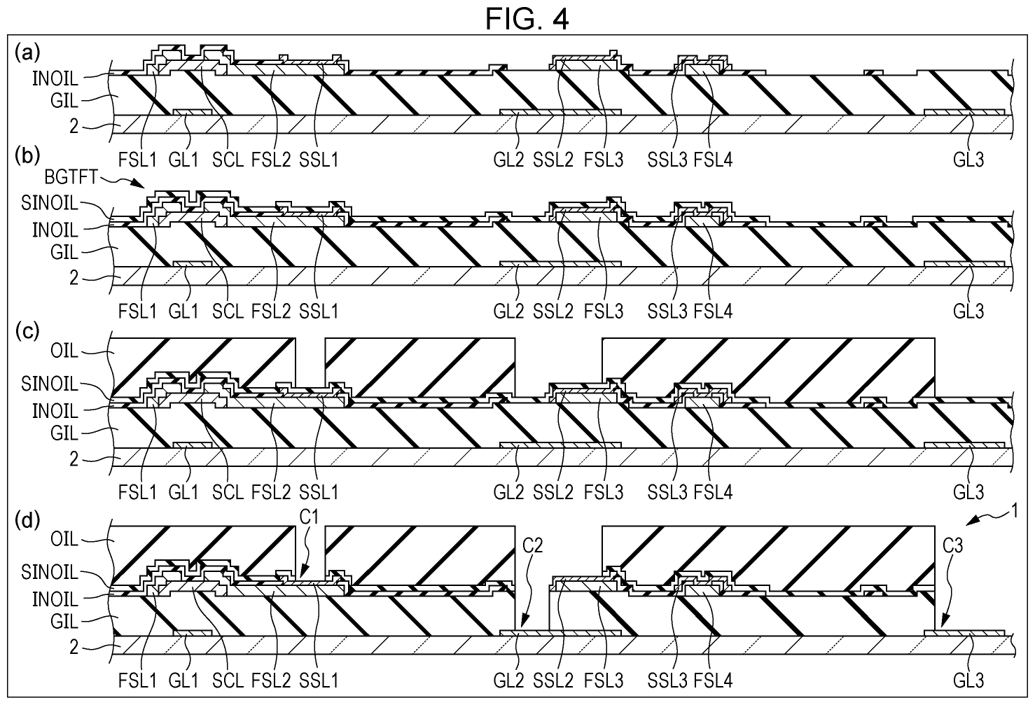

FIG. 2 is a diagram illustrating the production steps of the active matrix substrate 1. FIG. 3 is a diagram illustrating the steps from the step of forming a gate layer on the substrate 2 (S1) to the step of peeling the fourth resist (S17) of the production steps of the active matrix substrate 1 shown in FIG. 2. FIG. 4 is a diagram illustrating the steps from the step of forming the second source layer (S18) to the step of peeling the sixth resist (S28) of the production steps of the active matrix substrate 1 shown in FIG. 2.

Initially, as shown in FIG. 2, the step of forming the gate layer on the substrate 2 (S1), the step of patterning the first resist on the gate layer (S2), and the step of etching the gate layer by using the first resist as a mask (S3) are performed, and, thereafter, the step of peeling the first resist (S4) is performed. As a result, as shown in FIG. 3(a), the gate layers GL1, GL2, and GL3 having predetermined shapes are formed on the substrate 2.

Subsequently, as shown in FIG. 2, the step of forming the gate insulating film GIL (S5), the step of forming the semiconductor layer on the gate insulating film GIL (S6), the step of patterning the second resist on the semiconductor layer (S7), and the step of etching the semiconductor layer by using the second resist as a mask (S8) are performed, and, thereafter, the step of peeling the second resist (S9) is performed. As a result, as shown in FIG. 3(b), the gate layers GL1, GL2, and GL3 having predetermined shapes, the gate insulating film GIL, and the semiconductor layer SCL having a predetermined shape are formed on the substrate 2.

As shown in FIG. 2, the step of forming the first source layer on the semiconductor layer SCL and the gate insulating film GIL (S10), the step of patterning the third resist on the first source layer (S11), and the step of etching the first source layer by using the third resist as a mask (S12) are performed, and, thereafter, the step of peeling the third resist (S13) is performed. As a result, as shown in FIG. 3(c), the gate layers GL1, GL2, and GL3 having predetermined shapes, the gate insulating film GIL, the semiconductor layer SCL having a predetermined shape, and the first source layers FSL1 to FSL4 are formed on the substrate 2.

As shown in FIG. 2, the step of forming the first inorganic insulating film INOIL (S14) is performed. As a result, as shown in FIG. 3(d), the first inorganic insulating film INOIL is formed on the substrate 2.

As shown in FIG. 2, the step of patterning the fourth resist on the first inorganic insulating film INOIL (S15) and the step of etching the first inorganic insulating film INOIL by using the fourth resist as a mask (S16) are performed, and, thereafter, the step of peeling the fourth resist (S17) is performed. As a result, as shown in FIG. 3(e), the first inorganic insulating film INOIL having a predetermined shape is formed on the substrate 2. At this time, the contact hole C4 is formed in the first inorganic insulating film INOIL (refer to FIG. 1(b)).

As shown in FIG. 2, the step of forming the second source layer (S18), the step of patterning the fifth resist on the second source layer (S19), and the step of etching the second source layer by using the fifth resist as a mask (S20) are performed, and, thereafter, the step of peeling the fifth resist (S21) is performed. As a result, as shown in FIG. 4(a), the second source layers SSL1 to SSL3 having predetermined shapes are formed on the substrate 2.

As shown in FIG. 2, the step of forming the second inorganic insulating film SINOIL (S22) is performed. As a result, as shown in FIG. 4(b), the second inorganic insulating film SINOIL is formed on the substrate 2.

As shown in FIG. 2, the step of patterning the organic insulating film OIL (S23) is performed. As a result, as shown in FIG. 4(c), the organic insulating film OIL having a predetermined pattern is formed on the substrate 2.

As shown in FIG. 2, the step of performing etching by using the organic insulating film OIL as a mask to form the contact holes (S24) is performed. As a result, as shown in FIG. 4(d), the contact hole C1, the contact hole C2, and the contact hole C3 are formed.

As shown in FIG. 2, the step of forming the pixel electrode layer (S25), the step of patterning the sixth resist on the pixel electrode layer (S26), and the step of etching the pixel electrode layer by using the sixth resist as a mask (S27) are performed, and, thereafter, the step of peeling the sixth resist (S28) is performed. As a result, as shown in FIG. 1(a) and FIG. 1(b), the pixel electrode PIX1 having a predetermined shape and the conductive members PIX2 and PIX3 having predetermined shapes are formed on the substrate 2 so as to form the active matrix substrate 1.

In this regard, in the present embodiment, the positive-type resist or the negative-type resist is used as the first resist to the sixth resist, but the present embodiment is not limited to this. The first resist to the sixth resist are not limited to having photosensitivity as long as the resist can be patterned and the film under the resist can be etched by using the resist as a mask.

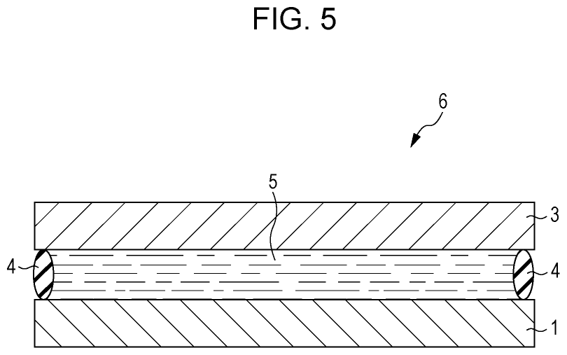

FIG. 5 is a diagram showing a schematic configuration of a display device 6 including the active matrix substrate 1.

In the present embodiment, a liquid crystal display device in which the active matrix substrate 1 and a counter substrate 3 provided with a common electrode layer (not shown in the drawing) opposing the active matrix substrate 1 are bonded to each other by a sealing material 4 and in which a liquid crystal layer 5 is provided between the active matrix substrate 1 and the counter substrate 3 will be described as an example of the display device 6, but the present embodiment is not limited to this. The display device 6 may be a display device including an OLED (organic light emitting diode), a display device including an inorganic light emitting diode or a QLED (quantum dot light emitting diode), or the like.

According to the above-described configuration, the display device 6 that includes the organic insulating film and the source wiring line composed of the two-layer wiring line and that is produced with a high yield can be realized.

### Second Embodiment

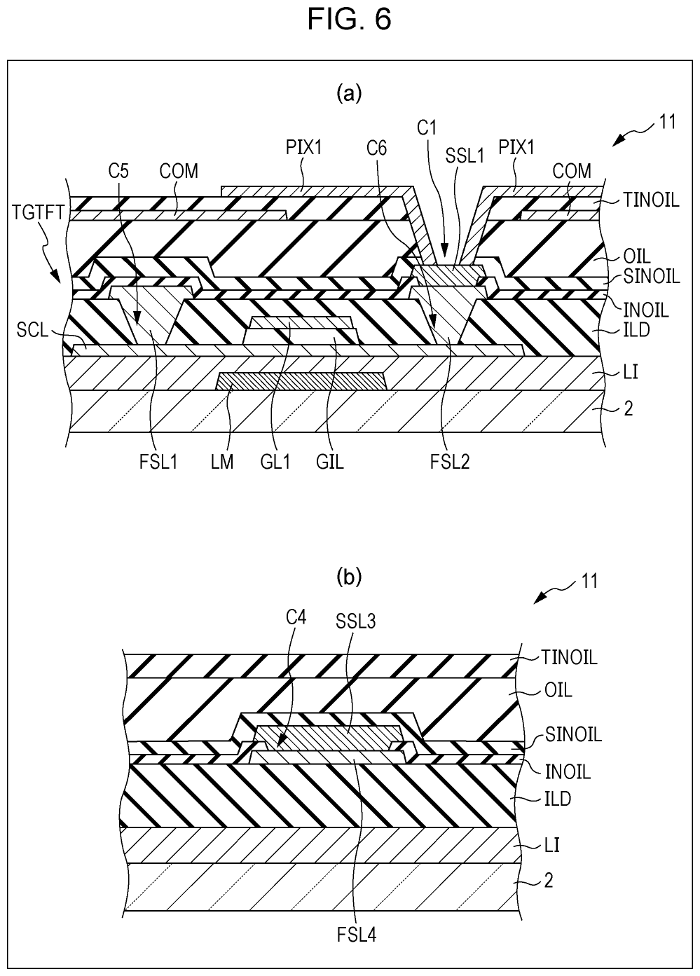

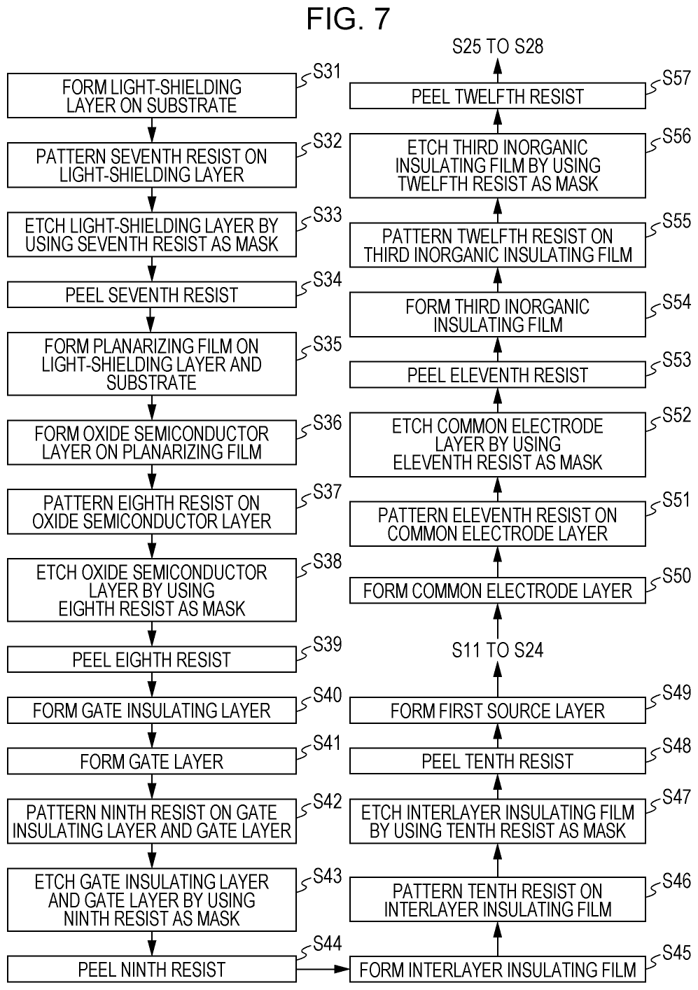

A second embodiment according to the present invention will be described below with reference to FIG. 6 and FIG. 7. The second embodiment is different from the first embodiment in that an active matrix substrate 11 includes a top-gate TFT element TGTFT. Other configurations are as described in the first embodiment. For the sake of facilitating explanations, the member having the same function as the member shown in the drawings of the first embodiment is indicated by the same reference numeral and explanations thereof will be omitted.

FIG. 6(a) is a diagram showing a region in which the TFT element TGTFT and the pixel electrode PIX1 are disposed in the active matrix substrate 11, and FIG. 6(b) is a diagram showing an end region including a terminal portion in the active matrix substrate 11.

As shown in FIG. 6(a) and FIG. 6(b), the active matrix substrate 11 has a two-layer wiring structure in each of the drain electrode portion of the TFT element TGTFT and the gate-source cross portion. Specifically, in the drain electrode portion of the TFT element TGTFT, the first source layer FSL2 and the second source layer SSL1 are stacked so as to constitute the two-layer wiring line. In the gate-source cross portion, the first source layer FSL4 and the second source layer SSL3 are stacked so as to constitute the two-layer wiring line.

As described above, the active matrix substrate 11 includes the organic insulating film OIL and the two-layer wiring structures composed of the first source layers FSL2 and FSL4 and the second source layers SSL1 and SSL3. However, since the second inorganic insulating film SINOIL is disposed between the second source layers SSL1 and SSL3 that are upper layers of the two-layer wiring structures and the organic insulating film OIL, the second source layers SSL1 and SSL3 are not in direct contact with the organic insulating film OIL. Therefore, the metal material constituting the second source layers SSL1 and SSL3 can be suppressed from reacting with oxygen or hydrogen contained in the organic insulating film OIL, and the metal material constituting the second source layers SSL1 and SSL3 can be suppressed from forming a metal oxide. Consequently, according to the above-described configuration, the active matrix substrate 11 that includes the organic insulating film OIL and the source wiring line composed of the two-layer wiring line and that is produced with a high yield can be realized.

The production steps of the active matrix substrate 11 will be described below with reference to FIG. 6 and FIG. 7.

FIG. 7 is a diagram illustrating the production steps of the active matrix substrate 11.

Initially, as shown in FIG. 7, the step of forming the light-shielding layer on the substrate 2 (S31), the step of patterning the seventh resist on the light-shielding layer (S32), and the step of etching the light-shielding layer by using the seventh resist as a mask (S33) are performed, and, thereafter, the step of peeling the seventh resist (S34) is performed. As a result, as shown in FIG. 6(a), the light-shielding layer LM having a predetermined shape is formed on the substrate 2. The light-shielding layer LM is a layer to suppress light from being incident on the oxide semiconductor layer SCL and is made of a metal material in the present embodiment, but the present embodiment is not limited to this. The light-shielding layer LM may be made of a resin material capable of blocking the light. In the case where the resin material capable of blocking the light is used, it is preferable that a highly heat-resistant resin capable of withstanding high-temperature steps be used.

As shown in FIG. 7, the step of forming a planarizing film LI on the light-shielding layer LM and the substrate 2 (S35) is performed. Regarding the planarizing film LI, for example, a silicon nitride film, a silicon film, a silicon oxynitride film, or the like may be used.

Subsequently, as shown in FIG. 7, the step of forming the oxide semiconductor layer on the planarizing film LI (S36), the step of patterning the eighth resist on the oxide semiconductor layer (S37), and the step of etching the oxide semiconductor layer by using the eighth resist as a mask (S38) are performed, and, thereafter, the step of peeling the eighth resist (S39) is performed. As a result, as shown in FIG. 6(a), the oxide semiconductor layer SCL having a predetermined shape is formed on the substrate 2. Regarding the oxide semiconductor layer SCL, for example, semiconductor layers containing In, Ga, and Zn may be used.

As shown in FIG. 7, the step of forming the gate insulating film (S40), the step of forming the gate layer (S41), the step of patterning the ninth resist on the gate insulating film and the gate layer (S42), and the step of etching the gate insulating layer and the gate layer by using the ninth resist as a mask (S43) are performed, and, thereafter, the step of peeling the ninth resist (S44) is performed. As a result, as shown in FIG. 6(a), the gate insulating film GIL and the gate layer GL1 that have predetermined shapes are formed on the substrate 2.

As shown in FIG. 7, the step of forming the interlayer insulating film (S45), the step of patterning the tenth resist on the interlayer insulating film (S46), and the step of etching the interlayer insulating film by using the tenth resist as a mask (S47) are performed, and, thereafter, the step of peeling the tenth resist (S48) is performed. As a result, as shown in FIG. 6(a), the interlayer insulating film ILD having a predetermined shape in which a contact hole C5 and a contact hole C6 are formed is formed on the substrate 2. Regarding the interlayer insulating film ILD, for example, a silicon nitride film, a silicon oxide film, a silicon oxynitride film, or the like may be used.

As shown in FIG. 7, the step of forming the first source layer (S49), the steps S11 to S24 in FIG. 2 described in the first embodiment, the step of forming a common electrode layer (S50), the step of patterning the eleventh resist on the common electrode layer (S51), and the step of etching the common electrode layer by using the eleventh resist as a mask (S52) are performed, and, thereafter, the step of peeling the eleventh resist (S53) is performed. As a result, as shown in FIG. 6(a), the common electrode layer COM having a predetermined shape is formed on the substrate 2. In this regard, for example, the common electrode layer COM may be made of ITO or IZO or be made of a metal material. In the first embodiment, the case in which the common electrode layer is disposed in the counter substrate 3 rather than the active matrix substrate 1 is described as an example. The active matrix substrate 11 according to the present embodiment includes the common electrode layer COM.

As shown in FIG. 7, the step of forming the third inorganic insulating film (S54), the step of patterning the twelfth resist on the third inorganic insulating film (S55), and the step of etching the third inorganic insulating film by using the twelfth resist as a mask (S56) are performed, and, thereafter, the step of peeling the twelfth resist (S57) is performed. As a result, as shown in FIG. 6(a) and FIG. 6(b), the third inorganic insulating film TINOIL having a predetermined shape is formed on the substrate 2. Regarding the third inorganic insulating film TINOIL, for example, a silicon nitride film, a silicon oxide film, a silicon oxynitride film, or the like may be used.

Subsequently, as shown in FIG. 7, the steps S25 to S28 in FIG. 2 described in the first embodiment are performed and, as a result, the active matrix substrate 11 shown in FIG. 6(a) and FIG. 6(b) is formed.

In this regard, in the present embodiment, the positive-type resist or the negative-type resist is used as the seventh resist to the twelfth resist, but the present embodiment is not limited to this. The seventh resist to the twelfth resist are not limited to having photosensitivity as long as the resist can be patterned and the film under the resist can be etched by using the resist as a mask.

### Third Embodiment

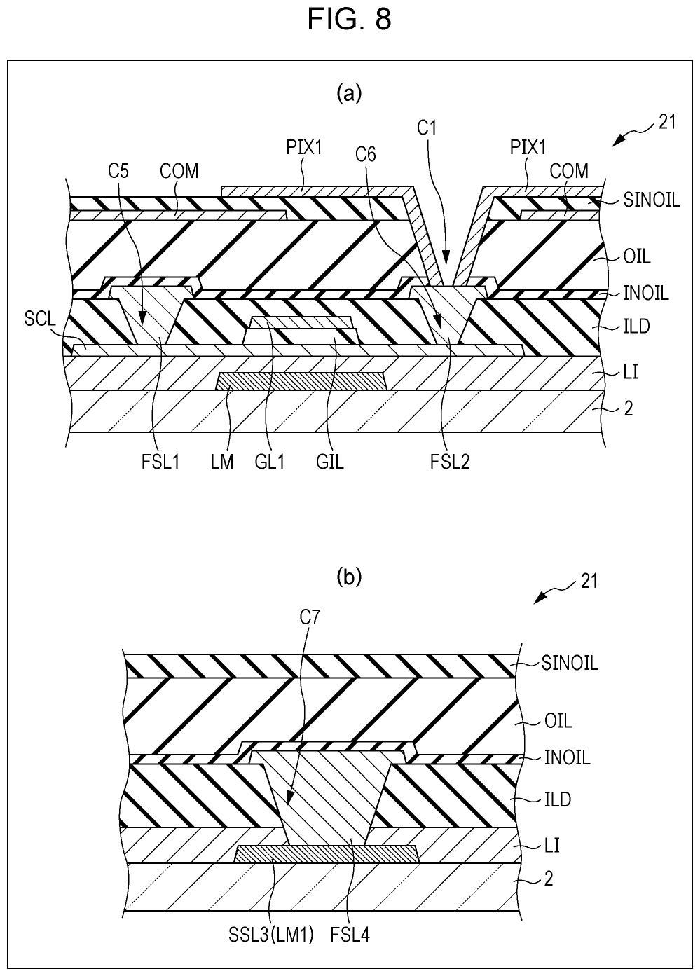

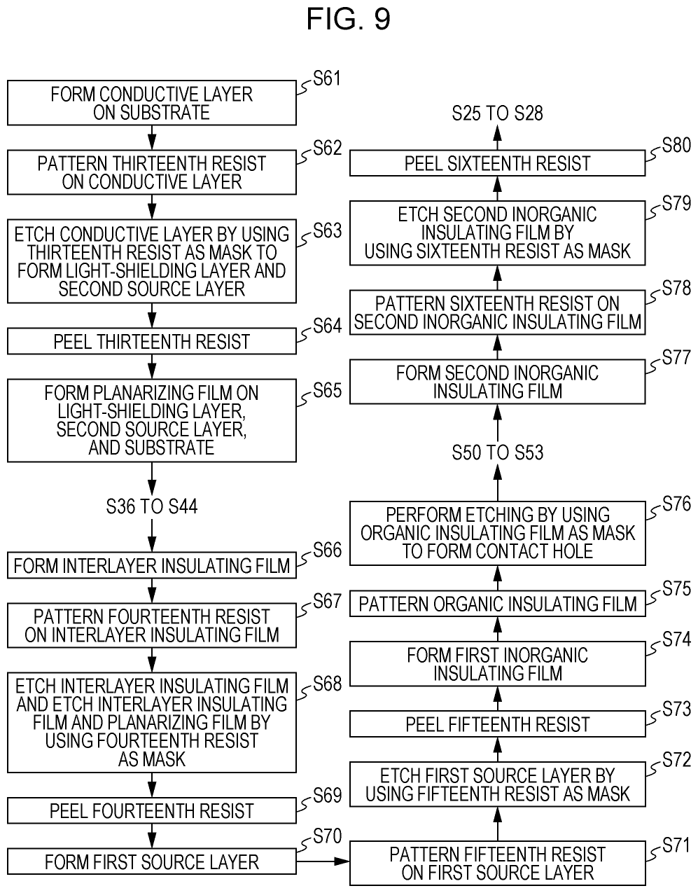

A third embodiment according to the present invention will be described below with reference to FIG. 8 and FIG. 9. The present embodiment is different from the second embodiment in that in the gate-source cross portion of an active matrix substrate 21 according to the present embodiment, the second source layer SSL3 (LM1) composed of the same layer as the light-shielding layer LM and the first source layer FSL4 are stacked so as to constitute a two-layer wiring line. Other configurations are as described in the first embodiment. For the sake of facilitating explanations, the member having the same function as the member shown in the drawings of the first embodiment is indicated by the same reference numeral and explanations thereof will be omitted.

FIG. 8(a) is a diagram showing a region in which the TFT element and the pixel electrode PIX1 are disposed in the active matrix substrate 21, and FIG. 8(b) is a diagram showing an end region including a terminal portion in the active matrix substrate 21.

As shown in FIG. 8(b), the active matrix substrate 21 has a two-layer wiring structure in the gate-source cross portion. Specifically, in the gate-source cross portion, the second source layer SSL3 (LM1) composed of the same layer as the light-shielding layer LM and the first source layer FSL4 are stacked so as to constitute a two-layer wiring line.

In this regard, in the active matrix substrate 21, the first source layers FSL1, FSL2, and FSL4 are layers upper than the second source layers LM and SSL3 (LM1).

To realize a reduction in resistance of the wiring line, the first source layers FSL1, FSL2, and FSL4 may be composed of a single-layer film of, for example, copper (Cu), silver (Ag), or molybdenum (Mo), a multilayer film which contains at least one of these metals and in which any one of copper (Cu), silver (Ag), and molybdenum (Mo) is present on the organic insulating film OIL side, or an alloy film of at least two of these metals.

The second source layer SSL3 (LM1) composed of the same layer as the light-shielding layer LM has to be composed of a conductive material and may be composed of a single-layer film of, for example, copper (Cu), silver (Ag), molybdenum (Mo), aluminum (Al), tungsten (W), tantalum (Ta), chromium (Cr), or titanium (Ti), a multilayer film which contains at least one of these metals, or an alloy film of at least two of these metals.

As described above, the active matrix substrate 21 includes the organic insulating film OIL and the two-layer wiring structure composed of the second source layer SSL3 (LM1) and the first source layer FSL4. However, since the first inorganic insulating film INOIL is disposed between the first source layer FSL4 that is an upper layer of the two-layer wiring structure and the organic insulating film OIL, the first source layer FSL4 is not in direct contact with the organic insulating film OIL. Therefore, the metal material constituting the first source layer FSL4 can be suppressed from reacting with oxygen or hydrogen contained in the organic insulating film OIL, and the metal material constituting the first source layer FSL4 can be suppressed from forming a metal oxide. Consequently, according to the above-described configuration, the active matrix substrate 21 that includes the organic insulating film OIL and the source wiring line composed of the two-layer wiring line and that is produced with a high yield can be realized.

The production steps of the active matrix substrate 21 will be described below with reference to FIG. 8 and FIG. 9.

FIG. 9 is a diagram illustrating the production steps of the active matrix substrate 21.

Initially, as shown in FIG. 9, the step of forming the conductive layer on the substrate 2 (S61), the step of patterning the thirteenth resist on the conductive layer (S62), and the step of etching the conductive layer by using the thirteenth resist as a mask to form the light-shielding layer LM and the second source layer SSL3 (LM1) (S63) are performed, and, thereafter, the step of peeling the thirteenth resist (S64) is performed. As a result, as shown in FIG. 8(a) and FIG. 8(b), the light-shielding layer LM having a predetermined shape and the second source layer SSL3 (LM1) having a predetermined shape are formed on the substrate 2.

Subsequently, as shown in FIG. 9, the step of forming a planarizing film LI on the light-shielding layer LM, the second source layer SSL3 (LM1), and the substrate 2 (S65), the steps S36 to S44 in FIG. 7 described in the second embodiment, the step of forming the interlayer insulating film (S66), the step of patterning the fourteenth resist on the interlayer insulating film (S67), and the step of etching the interlayer insulating film and etching the interlayer insulating film and the planarizing film LI by using the fourteenth resist as a mask (S68) are performed, and, thereafter, the step of peeling the fourteenth resist (S69) is performed. As a result, as shown in FIG. 8(a) and FIG. 8(b), the interlayer insulating film ILD having a predetermined shape in which the contact hole C5 and the contact hole C6 are formed and the interlayer insulating film ILD and the planarizing film LI in which a contact hole 7 is formed are formed on the substrate 2.

As shown in FIG. 9, the step of forming the first source layer (S70), the step of patterning the fifteenth resist on the first source layer (S71), and the step of etching the first source layer by using the fifteenth resist as a mask (S72) are performed, and, thereafter, the step of peeling the fifteenth resist (S73) is performed. As a result, as shown in FIG. 8(a) and FIG. 8(b), the first source layers FSL1, FSL2, and FSL4 having predetermined shapes are formed on the substrate 2.

As shown in FIG. 9, the step of forming the first inorganic insulating film (S74), the step of patterning the organic insulating film OIL (S75), and the step of performing etching by using the organic insulating film OIL as a mask to form the contact hole C1 in the first inorganic insulating film (S76) are performed. As a result, as shown in FIG. 8(a) and FIG. 8(b), the first inorganic insulating film INOIL having a predetermined shape and the organic insulating film OIL having a predetermined shape are formed on the substrate 2.

As shown in FIG. 9, the steps S50 to S53 in FIG. 7 described in the second embodiment, the step of forming the second inorganic insulating film (S77), the step of patterning the sixteenth resist on the second inorganic insulating film (S78), and the step of etching the second inorganic insulating film by using the sixteenth resist as a mask (S79) are performed, and, thereafter, the step of peeling the sixteenth resist (S80) is performed. As a result, as shown in FIG. 8(a) and FIG. 8(b), the second inorganic insulating film SINOIL having a predetermined shape is formed on the substrate 2.

As shown in FIG. 9, the steps S25 to S28 in FIG. 2 described in the first embodiment are performed. As a result, the active matrix substrate 21 shown in FIG. 8(a) and FIG. 8(b) is formed.

In this regard, in the present embodiment, the positive-type resist or the negative-type resist is used as the thirteenth resist to the sixteenth resist, but the present embodiment is not limited to this. The thirteenth resist to the sixteenth resist are not limited to having photosensitivity as long as the resist can be patterned and the film under the resist can be etched by using the resist as a mask.

The present invention is not limited to the above-described embodiments, and various modifications within the scope of the claims can be applied. Embodiments obtained by appropriately combining technical measures disclosed in different embodiments are included in the technical scope of the present invention. Further, new technical features can be created by combining technical measures disclosed in the individual embodiments.

### INDUSTRIAL APPLICABILITY

The present disclosure can be applied to an active matrix substrate, a display device, and a method for manufacturing an active matrix substrate.

### REFERENCE SIGNS LIST

1 active matrix substrate
2 substrate
3 counter substrate
4 sealing material
5 liquid crystal layer
6 display device
11 active matrix substrate
21 active matrix substrate
GL1 to GL3 gate layer
GIL gate insulating film
SCL semiconductor layer
FSL1 to FSL4 first source layer (first conductive layer)
INOIL first inorganic insulating film
SINOIL second inorganic insulating film
TINOIL third inorganic insulating film
SSL1 to SSL3 second source layer (second conductive layer)
OIL organic insulating film
PIX1 pixel electrode
PIX2, PIX3 conductive member
C1 to C7 contact hole
BGTFT bottom-gate transistor element
TGTFT top-gate transistor element
LM light-shielding layer
LI planarizing film
ILD interlayer insulating film
COM common electrode layer

1. An active matrix substrate comprising a substrate provided with a first conductive layer, a second conductive layer, and an organic insulating film,
wherein the first conductive layer and the second conductive layer are partly stacked,
the organic insulating film is arranged further than the first conductive layer and the second conductive layer from the substrate, and
of the first conductive layer and the second conductive layer, the conductive layer arranged further from the substrate is in contact with the organic insulating film with an inorganic insulating film interposed therebetween.

2. The active matrix substrate according to claim 1,
wherein a bottom-gate transistor element including a source electrode, a drain electrode, a semiconductor layer, and a gate electrode arranged nearer than the semiconductor layer to the substrate is included,
the first conductive layer is arranged nearer than the second conductive layer to the substrate, and
the first conductive layer is composed of the same layer as the source electrode and the drain electrode.

3. The active matrix substrate according to claim 1,
wherein a top-gate transistor element including a source electrode, a drain electrode, a semiconductor layer, and a gate electrode arranged further than the semiconductor layer from the substrate is included,
the first conductive layer is arranged nearer than the second conductive layer to the substrate, and
the first conductive layer is composed of the same layer as the source electrode and the drain electrode.

4. The active matrix substrate according to claim 1,
wherein a top-gate transistor element including a source electrode, a drain electrode, a semiconductor layer, a gate electrode arranged further than the semiconductor layer from the substrate, and a light-shielding layer arranged nearer than the source electrode, the drain electrode, and the semiconductor layer to the substrate is included,
the first conductive layer is arranged further than the second conductive layer from the substrate,
the first conductive layer is composed of the same layer as the source electrode and the drain electrode, and
the second conductive layer is composed of the same layer as the light-shielding layer.

5. The active matrix substrate according to claim 1,
wherein the second conductive layer in contact with the organic insulating film with the inorganic insulating film interposed therebetween is composed of one film selected from
a single-layer film made of any one of copper, silver, and molybdenum,
a multilayer film which contains at least one of copper, silver, and molybdenum and in which any one of copper, silver, and molybdenum is present on the organic insulating film side, and
an alloy film of at least two of copper, silver, and molybdenum.

6. The active matrix substrate according to claim 1,
wherein the first conductive layer in contact with the organic insulating film with the inorganic insulating film interposed therebetween is composed of one film selected from
a single-layer film made of any one of copper, silver, and molybdenum,
a multilayer film which contains at least one of copper, silver, and molybdenum and in which any one of copper, silver, and molybdenum is present on the organic insulating film side, and
an alloy film of at least two of copper, silver, and molybdenum.

7. The active matrix substrate according to claim 2, wherein the semiconductor layer is an oxide semiconductor layer.

8. A display device including the active matrix substrate according to claim 1.

9. The display device according to claim 8, wherein the active matrix substrate and a counter substrate arranged opposing the active matrix substrate are included.

10. A method for manufacturing an active matrix substrate comprising the steps of, on a substrate, forming a first conductive layer, forming a second conductive layer, and forming an organic insulating film,
wherein in the forming of a first conductive layer and the forming of a second conductive layer, the first conductive layer and the second conductive layer are partly stacked, and
forming an inorganic insulating film so as to cover the conductive layer, of the first conductive layer and the second conductive layer, arranged further from the substrate is performed after the forming of a first conductive layer and the forming of a second conductive layer and before the forming of an organic insulating film.

11. The method for manufacturing an active matrix substrate according to claim 10,
wherein the forming of a first conductive layer is performed before the forming of a second conductive layer, and
in the forming of a first conductive layer, the first conductive layer is composed of the same layer as a source electrode and a drain electrode of a bottom-gate transistor element including the source electrode, the drain electrode, a semiconductor layer, and a gate electrode arranged nearer than the semiconductor layer to the substrate.

12. The method for manufacturing an active matrix substrate according to claim 10,
wherein the forming of a first conductive layer is performed before the forming of a second conductive layer, and
in the forming of a first conductive layer, the first conductive layer is composed of the same layer as a source electrode and a drain electrode of a top-gate transistor element including the source electrode, the drain electrode, a semiconductor layer, and a gate electrode arranged further than the semiconductor layer from the substrate.

13. The method for manufacturing an active matrix substrate according to claim 10,
wherein the forming of a second conductive layer is performed before the forming of a first conductive layer, and
in the forming of a first conductive layer, the first conductive layer is composed of the same layer as a source electrode and a drain electrode of a top-gate transistor element including the source electrode, the drain electrode, a semiconductor layer, a gate electrode arranged further than the semiconductor layer from the substrate, and a light-shielding layer arranged nearer than the source electrode, the drain electrode, and the semiconductor layer to the substrate,
and in the forming of a second conductive layer, the second conductive layer is composed of the same layer as the light-shielding layer.
